(19) United States
(12) Patent Application Publication
(10) Pub. No.: US 2008/0057637 A1
(43) Pub. Date: Mar. 6, 2008

(54) Method for manufacturing semiconductor device

(75) Inventor: Kee Joon Choi, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu HiTek Co., Ltd.

(21) Appl. No.: 11/896,040

(22) Filed: Aug. 29, 2007

(30) Foreign Application Priority Data
Aug. 30, 2006 (KR) 10-2006-0083177

(51) Int. Cl. H01L 21/8238

(52) U.S. Cl. 438/199; 257/E21.632

(57) ABSTRACT

A method is provided for manufacturing a semiconductor device. The method may be capable of simplifying the formation of wells by reducing the number of process steps. In the method for manufacturing a semiconductor device including a high voltage device and a low voltage device, a P-well is formed simultaneously with a P-drift region, and an N-well is formed simultaneously with an N-drift region, so that the wells and drift regions are formed in one process, thereby reducing the manufacturing cost and time, and improving the yield rate.

The present application claims the benefit of priority under 35 U.S.C. 119 to Korean Patent Application No. 10-2006-0083177, filed on Aug. 30, 2006, the entire contents of which are incorporated herein by reference.

### BACKGROUND

The present invention relates to a method for manufacturing a semiconductor device. More particularly, the present invention relates to a method capable of forming wells with a reduced number of process steps.

In general, an LDI (LCD Driver IC) includes a Controller IC, a Source Driver IC, and a Gate Driver IC, which are provided in the form of two or three separate chips.

Recently, the advent of one-chip solution for mobile communication devices initiated the usage of HV (High Voltage)/MV (Medium Voltage)/LV (Low Voltage) processes. Accordingly, a new LDI process has been developed.

Conventionally, various processes, such as a logic process and a high voltage (HV) process, have been simultaneously performed using masks dedicated therefor, thus remarkably increasing the number of masks used. According to the related art, an N-well, a P-well, an N-drift, and a P-drift for the high voltage device, and an N-well and a P-well for the low voltage device are individually formed, so that six distinct patterns are used to form the wells, thus increasing the manufacturing cost and the process time.

### SUMMARY

In light of the above, a new method for manufacturing a semiconductor device has been developed, which is capable of simplifying the process for forming wells in an LDI (LCD Driver IC) including a high voltage device and a low voltage device.

In one embodiment, there is provided a method for manufacturing a semiconductor device, the method including: selectively implanting P-type impurities into an N-type substrate, selectively implanting N-type impurities into the N-type substrate, diffusing the P-type impurities and the N-type impurities to form a P-drift and a P-well of the high voltage device, and a P-well of the low voltage device, and to form an N-drift and an N-well of the high voltage device, and an N-well of the low voltage device, implanting impurities for controlling a threshold voltage into channels of the high voltage device and the lower voltage device, and forming a gate oxide and a gate electrode on each of the high voltage device and the low voltage device.

Other features consistent with the present invention will be, or will become, apparent to one skilled in the art upon examination of the following figures and detailed description.

### BRIEF DESCRIPTION OF THE DRAWING

FIGS. 1A to 1E are sectional views illustrating a method for manufacturing a semiconductor device consistent with the present invention.

### DETAILED DESCRIPTION

Hereinafter, a method for manufacturing a semiconductor device consistent with the present invention, will be described with reference to the accompanying drawings.

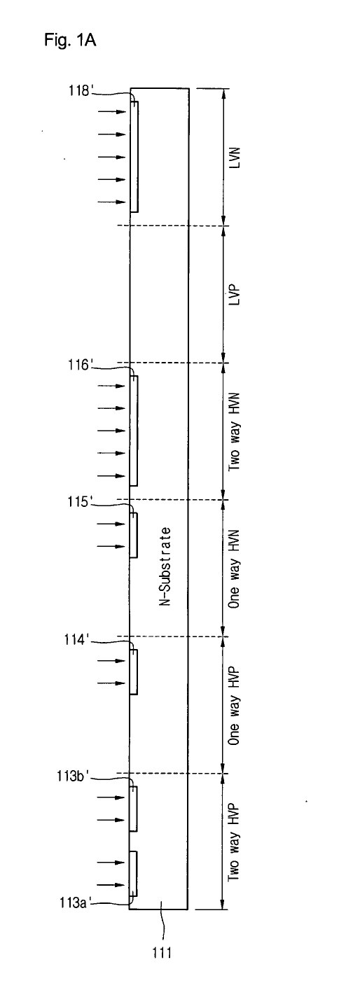

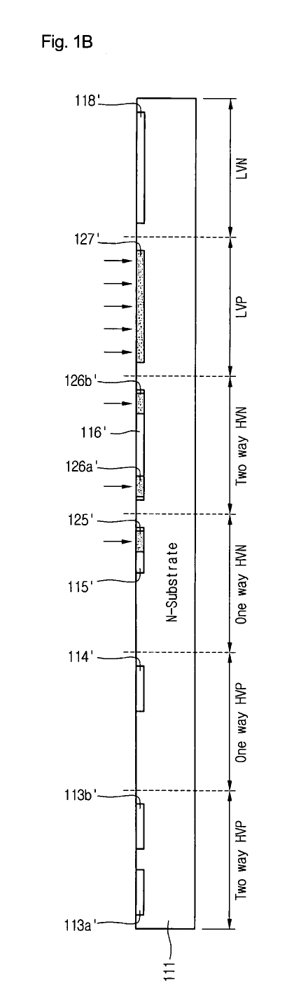

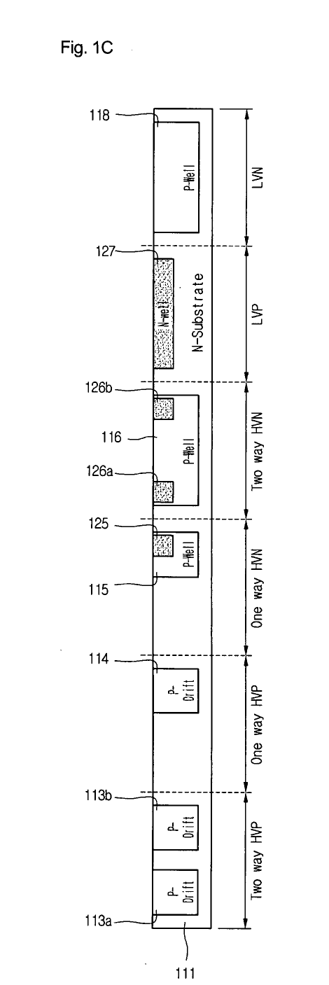

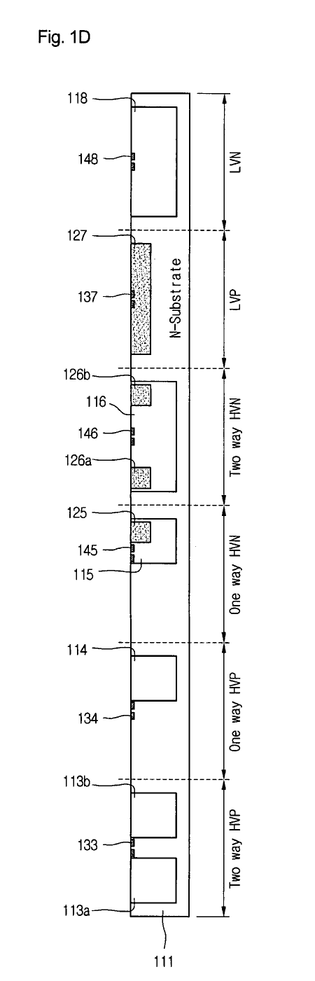

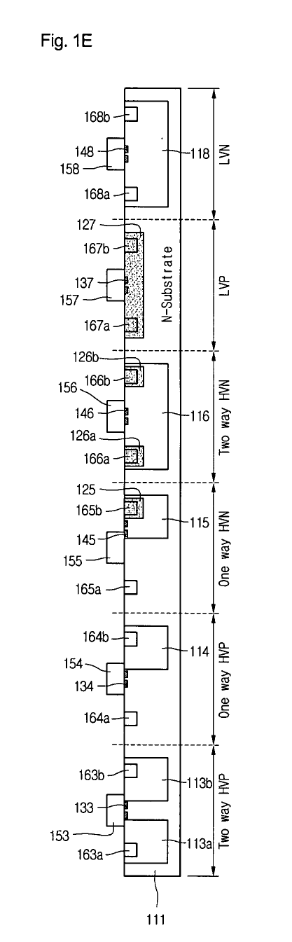

FIGS. 1A to 1E are sectional views illustrating a method for manufacturing a semiconductor device consistent with the present invention.

A semiconductor device may include a low voltage device and a high voltage device, and may be classified as a PMOS (P-channel Metal Oxide Semiconductor) and an NMOS (N-channel Metal Oxide Semiconductor). In addition, the semiconductor device may be classified as a two-way type and a one-way type, according to the configuration (symmetric or asymmetric configuration) of a symmetrical drift region of the semiconductor device. Thus, the semiconductor device may include a two-way HVP (High Voltage P-channel) region, a one-way HVP (High Voltage P-channel) region, a one-way HVN (High Voltage N-channel) region, a two-way HVN (High Voltage N-channel) region, an LVP (Low Voltage P-channel) region, and an LVN (Low Voltage N-channel) region.

In a method for manufacturing the semiconductor device having the high voltage device and the low voltage device, a P-well may be formed simultaneously with a P-drift region, and an N-well may be formed simultaneously with an N-drift region. Accordingly, the drifts and the wells may be formed in one process, so that the process for forming the wells may be simplified, thereby reducing manufacturing cost and manufacturing time, and improving yield rate.

As shown in FIG. 1A, a P-well pattern is formed on an N-type substrate 111, and P-type impurities, such as Boron (B), may be selectively implanted into N-type substrate 111. As a result, P-type impurity regions 113a′, 113b′, 114′, 115′, 116′, and 118′ are formed in the two-way HVP region, the one-way HVP region, the one-way HVN region, the two-way HVN region, and the LVN region, respectively.

As shown in FIG. 1B, an N-well pattern is formed on N-type substrate 111, and N-type impurities, such as Arsenic (As), may be selectively implanted into N-type substrate 111. As a result, N-type impurity regions 125′, 126a′, 126b′, and 127′ are formed in the one-way HVN region, the two-way HVN region, and the LVP region, respectively. In one embodiment, the dose of N-type impurities and P-type impurities may be about 5E12 (atoms/cm³).

Then, as shown in FIG. 1C, N-type substrate 111, into which impurities are implanted, is subject to a drive-in process, so that P-type impurities regions 113a′, 113b′, 114′, 115′, 116′, and 118′, and N-type impurities regions 125′, 126a′, 126b′, and 127′ are provided in the form of a deep well. As a result, P-drifts 113a and 113b are formed in the two-way HVP region of N-type substrate 111, and a P-drift 114 is formed in the one-way HVP region of N-type substrate 111. In addition, an N-drift 125 is formed on a P-well 115 of the one-way HVN region, and N-drifts 126a and 126b are formed on two end portions of a P-well 116 of the two-way HVN region. Moreover, an N-well 127 and a P-well 118 are respectively formed on the LVP and the LVN regions of the low voltage device.

In this case, even if the P-type impurities and the N-type impurities are subject to the driven-in process under the same condition, the diffusion coefficients of the P-type impurities and the N-type impurities are different from each other, so that N-drifts are formed in P-wells. In one embodiment, the dose of the P-type impurities may be about 1E13 (atoms/cm³), and the dose of the N-type impurities may be about 2E13 (atoms/cm³). That is, according to one embodiment, a P-well may be formed simultaneously with a P-drift region, and an N-well may be formed simultaneously with an N-drift region, so that the wells and the drifts may be formed in one process, thereby simplifying the process for forming the wells.

After that, as shown in FIG. 1D, P-type impurities 133, 134, and 137 for controlling the threshold voltage are implanted into the two-way HVP region, the one-way HVP region, and the LVP region, respectively, and N-type impurities 145, 146, and 148 for controlling the threshold voltage are implanted into the one-way HVN region, the two-way HVN region, and the LVN region, respectively.

Finally, as shown in FIG. 1E, gate oxides and/or poly-silicon gate electrodes 153, 154, 155, 156, 157, and 158, source and/or drain regions 163a, 163b, 164a, 164b, 165a, 165b, 166a, 166b, 167a, 167b, 168a, and 168b, and source and/or drain electrodes (not shown) are formed on the high voltage device region and the low voltage device, respectively.

Thus, fewer number of patterns may be used for forming the wells, so that the manufacturing cost is reduced. In addition, the stability can be ensured independently from a heat process through implantation of the impurities for controlling the threshold voltage. In addition, the P-wells and the N-wells are formed through a single drive-in process using the diffusion coefficient difference between the P-type impurities and the N-type impurities.

In the method for manufacturing the semiconductor device including the high voltage device and the low voltage device, the P-well may be formed simultaneously with the P-drift region, and the N-well may be formed simultaneously with the N-drift region, so that the wells and drifts are formed in one process. Accordingly, the process for forming the wells may be simplified, and the manufacturing cost and time are reduced, thereby improving the yield rate of the semiconductor device.

While embodiments consistent with the present invention has been described in detail, it will be apparent to those skilled in the art that various modifications and variations can be made to the embodiments. Thus, it is intended that the various modifications and variations of the embodiments fall within the scope of the appended claims and their equivalents.

What is claimed is:

1. A method for manufacturing a semiconductor device including a high voltage device and a low voltage device, the method comprising:
selectively implanting P-type impurities into an N-type substrate;
selectively implanting N-type impurities into the N-type substrate;
diffusing the P-type impurities and the N-type impurities to form a P-drift and a P-well of the high voltage device, and a P-well of the low voltage device, and to form an N-drift and an N-well of the high voltage device, and an N-well of the low voltage device;
implanting impurities for controlling a threshold voltage into channels of the high voltage device and the lower voltage device; and
forming a gate oxide and a gate electrode on each of the high voltage device and the low voltage device.

2. The method according to claim 1, wherein the high voltage device includes an HVPMOS (High Voltage P-channel Metal-Oxide Semiconductor), and an HVNMOS (High Voltage N-channel Metal-Oxide Semiconductor), and the low voltage device includes an LVNMOS (Low Voltage N-channel Metal-Oxide Semiconductor), and an LVPMOS (Low Voltage P-channel Metal-Oxide Semiconductor).

3. The method according to claim 2, wherein the P-drift of the HVPMOS is simultaneously formed with the P-well of the HVNMOS and the P-well of the LVNMOS.

4. The method according to claim 2, wherein the N-drift of the HVNMOS is simultaneously formed with the N-well of the LVPMOS.
